(19) United States
(12) Patent Application Publication
(10) Pub. No.: US 2012/0263876 A1
(43) Pub. Date: Oct. 18, 2012

(54) DEPOSITION OF SILICON DIOXIDE ON HYDROPHOBIC SURFACES

(75) Inventors: Suvi Haukka, Helsinki (FI); Marko Tuominen, Helsinki (FI)

(73) Assignee: ASM IP HOLDING B.V., Almere (NL)

(21) Appl. No.: 13/371,923

(22) Filed: Feb. 13, 2012

Related U.S. Application Data
(60) Provisional application No. 61/442,625, filed on Feb. 14, 2011.

(51) Int. Cl. C23C 16/40

(52) U.S. Cl. 427/255.18

(57) ABSTRACT

Methods for forming silicon dioxide thin films on hydrophobic surfaces are provided. For example, in some embodiments, silicon dioxide films are deposited on porous, low-k materials. The silicon dioxide films can be deposited using a catalyst and a silanol. In some embodiments, an undersaturated dose of one or more of the reactants can be used in forming a pore-sealing layer over a porous material.

### REFERENCE TO RELATED APPLICATIONS

The present application claims priority to U.S. provisional application No. 61/442,625, filed Feb. 14, 2011, which is hereby incorporated by reference in its entirety.

### BACKGROUND OF THE INVENTION

1. Field of the Invention

The present application relates generally to deposition of silicon dioxide thin films on hydrophobic surfaces, such as low-k films. The silicon dioxide films may serve, for example, as pore-sealing layers on porous low-k films.

2. Description of the Related Art/Background

Thin films comprising silicon dioxide are used in many different applications in microelectronic devices, for example, as dielectric materials. Silicon dioxide is one of the most commonly used dielectric materials in silicon microelectronic devices. However, silicon dioxide processes for deposition on hydrophobic surfaces without destroying the hydrophobicity have been difficult to develop.

In order to decrease the k-value of low k materials, the low-k materials can have increased porosity and carbon content providing the hydrophobicity. The porosity, however, makes it very challenging to deposit ultra thin, uniform and continuous barrier layers on the low-k surface. While ALD may be used to seal the pores of extremely low-k (ELK) materials prior to copper barrier deposition, the proper reactive sites need to be present on the low-k surface to achieve a continuous, pin-hole free layer. A low-k material with a hydrophilic surface (Si—OH) can be used; however, to keep the k-value intact, a hydrophobic surface (Si—CH₃) is desired. The hydrophobic surface may be oxidized to facilitate subsequent deposition. However, the oxidation process (Si—CH₃ to Si—OH) either with O₂-plasma or oxygen containing plasma or ozone can be difficult to control and as a result it is difficult to oxidize just the top-most surface layer. Rather, oxidation is likely to take place deep in the porous low-k layer as well, leading to an undesired increase in the k-value. This oxidation has restricted the use of ALD for pore-sealing purposes and for deposition of SiO₂ on hydrophobic surfaces generally.

### SUMMARY OF THE INVENTION

In accordance with one aspect of the present invention, methods of depositing a silicon dioxide film on a hydrophobic surface of a substrate are provided. In some embodiments, the methods comprise one or more deposition cycles, where each deposition cycle comprises: contacting a hydrophobic surface of a substrate with a vapor phase pulses of a catalytic chemical to form catalytic sites on the hydrophobic surface and subsequently contacting the formed catalytic sites with a silanol, thereby forming a silicon dioxide layer on the hydrophobic surface. In some embodiments the silicon dioxide layer is formed on the hydrophobic surface, but not on other surfaces of the substrate where there are no catalytic sites present. A catalytic chemical that is reactive with the hydrophobic surface is preferably selected prior to beginning the deposition process. In some embodiments the catalytic chemical is reactive with siloxane bridges on the substrate surface. In some embodiments the substrate surface is not treated to form hydroxyl groups prior to contacting the surface with the catalytic chemical.

The catalytic chemical may comprise a metal, such as aluminum, zinc or boron. In some embodiments the catalytic chemical is an alkylaluminum, alkylboron or alkylzinc compound, such as trimethyl aluminum (TMA), diethyl zinc, or triethyl boron (TEB). The silanol may be selected, for example, from tris(tertbutoxy)silanol, (^{t}BuO)₃SiOH and tris(tertpentoxy)silanol. In some embodiments the silanol comprises tris(tert-pentoxy)silanol. The thickness of the silicon dioxide film is less than about 2 nm in some embodiments.

In some embodiments the hydrophobic surface is a porous, low-k film. In some embodiments the hydrophobic surface is one that comprises CH₃ groups and/or siloxane bridges. In some embodiments the hydrophobic surface does not comprise —OH groups, for example as determined by IR or NMR. In some embodiments the hydrophobic surface has less than about 1 OH-group per nm², less than 0.5 OH-groups per nm², less than about 0.1 OH-groups per nm², or less than preferably less than about 0.05 OH-group per nm². In some embodiments the OH-group concentration might be below 0.01 per nm².

In some embodiments, the deposition temperature is between an bout 50° C. and about 400° C. In some embodiments the deposition temperature is greater than about 100° C. and the catalytic chemical is an alkylaluminum compound, such as TMA. In some embodiments the catalytic chemical is an alkylboron compound, such as TEB, and the deposition temperature is between about 50° C. and about 400° C., between about 100° C. and about 350° C., or between about 100° C. and about 300° C. In some embodiments the catalytic chemical is an alkylboron compound and the temperature is greater than about 100° C. In some embodiments the deposition temperature is greater than about 300° C. and the catalytic chemical is TEB.

In some embodiments a predetermined dose of the catalytic chemical and or the silicon reactant are used. For example, a predetermined, undersaturating dose of the catalytic chemical can be used to limit penetration into the pores of a porous low-k material prior to the exposure to the silanol compound. Such embodiments can be used, for example, to form a sealing layer.

In some embodiments a silicon dioxide layer of less than 3 nm or less than 2 nm is formed.

In some embodiments the silicon dioxide layer is deposited on a three-dimensional structure, such as a damascene structure, trenches or vias.

In another aspect, methods of sealing a porous low-k material are provided, where the porous low-k material comprises a hydrophobic surface. A vapor phase pulse of a catalyst are provided into a reaction chamber holding a substrate comprising the low-k material. The pulse of the catalyst is an under-saturated dose such that it penetrates only to a limited depth in the low-k material, preferably to depth of less than about 20 nm, more preferably to the depth of less than about 10 nm and most preferably to the depth of less than about 5 nm. Excess catalyst is removed and a vapor phase pulse of a silicon reactant, preferably a silanol, is provided and contacts the substrate, such that silicon dioxide is deposited to the depth of penetration of the catalyst. The penetration depth of the deposited film is dependent, in part, on size of precursor versus the pore size. Smaller pore dimensions may not limit the penetration of the catalyst but may limit the penetration of the silanol precursor. By limiting the depth of deposition a sealing layer is formed that does not significantly change the desired properties of the porous layer. It may be noted that the catalyst penetration depth is not the only factor determining the thickness of the pore sealing layer, but also the physical size of the silanol molecule and the pore dimensions.

For purposes of summarizing the invention and the advantages achieved over the prior art, certain objects and advantages of the invention have been described herein above. Of course, it is to be understood that not necessarily all such objects or advantages may be achieved in accordance with any particular embodiment of the invention. Thus, for example, those skilled in the art will recognize that the invention may be embodied or carried out in a manner that achieves or optimizes one advantage or group of advantages as taught herein without necessarily achieving other objects or advantages as may be taught or suggested herein.

All of these embodiments are intended to be within the scope of the invention herein disclosed. These and other embodiments of the present invention will become readily apparent to those skilled in the art from the following detailed description of the preferred embodiments having reference to the attached figures, the invention not being limited to any particular preferred embodiment(s) disclosed.

### BRIEF DESCRIPTION OF THE DRAWINGS

FIG. 1 is a flow chart generally illustrating a method for forming silicon dioxide thin films in accordance with some embodiments.

FIG. 2 illustrates the reaction of a catalyst, TMA, with oxygen bridge (Si—O-Si) sites on a substrate surface.

FIGS. 3A and B illustrate the reaction of a catalyst, TMA, with a low-k Si—CH₃ surface.

FIGS. 4A and B are TEM images of low-k 2.3 film before (FIG. 4A), i.e. pristine low-k film, and after (FIG. 4B) the reaction of a catalyst, TMA, with a low-k 2.3, and the catalytic growth of SiO₂.

### DETAILED DESCRIPTION OF THE PREFERRED EMBODIMENT

Silicon dioxide films can be deposited by silanol exposure to hydrophobic surfaces that have been exposed to an appropriate catalyst. Catalysts are selected that are reactive with the hydrophobic surface, such as with siloxane bridges (Si—O—Si). The catalyst prepares the surface for reaction with a silanol that leads to catalytic silicon dioxide growth. In some embodiments the catalyst is able to react with the hydrophobic surface and catalyze silicon dioxide growth from a silanol even if no hydroxyl groups are present on the substrate surface.

While primarily illustrated in the context of forming a silicon dioxide layer on porous low-k materials, the skilled artisan will readily appreciate the application of the principles and advantages disclosed herein to various contexts in which silicon dioxide films are useful. For example, silicon dioxide can be used in many electronic devices, such as capacitors, magnetic heads, flexible substrates for display and solar applications, MEMS devices, STI, protective layers for gate stacks, and sidewall spacers, etc.

It may be noted that with the term “silanol” is meant alkoxysilanols, preferably alkoxysilanols comprising a linear or branched, substituted or unsubstituted C₁-C₁₅ alkoxy group, more preferably C₁-C₈ alkoxy group, and OH-group attached the silicon atom.

In the processes described herein, multiple molecular layers of silicon dioxide may be deposited in each cycle. The number of monolayers of silicon dioxide deposited is mainly determined by reaction temperature and silanol dose. In some embodiments, however, only one monolayer of silicon dioxide is deposited.

Briefly, a catalyst is selected that is able to react with a hydrophobic surface on which deposition is desired. As discussed further below, in some embodiments the hydrophobic surface comprises siloxane bridges. Further, in some embodiments, the hydrophobic surface does not comprise any hydroxyl groups, or does not comprise a significant amount of hydroxyl groups.

In some embodiments the catalyst is an alkylaluminium, alkylboron or alkylzinc compound that is able to react with the hydrophobic surface. For example, the catalyst may comprise trimethyl aluminum (TMA), triethylboron (TEB), or diethyl zinc. In some embodiments the catalyst comprises a compound having the formula MRₓA₃₋ₓ, wherein x is from 1 to 3, R is a C₁-C₅ alkyl ligand, M is B or Al and A is a halide, alkylamine, amino, silyl or derivative thereof. In some embodiments the R is a C₁-C₃ alkyl ligand. In some embodiment the R is a methyl or ethyl group. In some embodiments the M is boron. In some embodiments the catalyst is ZnRₓA₂₋ₓ, wherein x is from 1 to 2, R is a C₁-C₅ alkyl ligand, and A is a halide, alkylamine, amino, silyl or derivative thereof. In some such embodiments the R is a C₁-C₃ alkyl ligand. In some embodiment the R is a methyl or ethyl group. Because a catalyst is selected that is reactive with the hydrophobic surface, the surface does not need to be oxidized or otherwise converted to a hydrophilic surface prior to providing the catalyst. Thus in some embodiments the surface is not treated to form hydroxyl groups (—OH) on the surface prior to contacting the surface with the catalyst.

The catalyst is provided into a reaction space comprising the substrate with the hydrophobic surface on which deposition is desired. The catalyst is contacted with the hydrophobic surface and forms up to a molecular layer of catalytic sites on the hydrophobic substrate surface. The substrate is then exposed to silanol, such as TPS, and a SiO₂ film is formed, typically comprising multiple molecular layers. The cycle can be repeated, if necessary, to deposit a silicon dioxide film of a desired thickness. In some embodiments, the concentration of the silanol can be controlled to achieve a desired deposition rate.

Without wishing to be held to any particular theory, it is believed that the catalyst adsorbed on the substrate surface initiates growth of siloxane polymer chains and the cross-linking of the polymers to form a dense SiO₂ film. Additional silanol diffuses through the cross-linked film to reach the bottom interface where the catalyst is located. The additional silanol reactant is then cross-linked, increasing the film thickness. See, for example, Burton et al. Chem. Mater. 2008 20:7031-7034 and Hausmann et al. Science 2002 298:402-406, both of which are incorporated by reference herein. Given a saturating pulse of silanol, the thickness of the film deposited in each cycle is thus determined by how far the silanol can diffuse through the growing film.

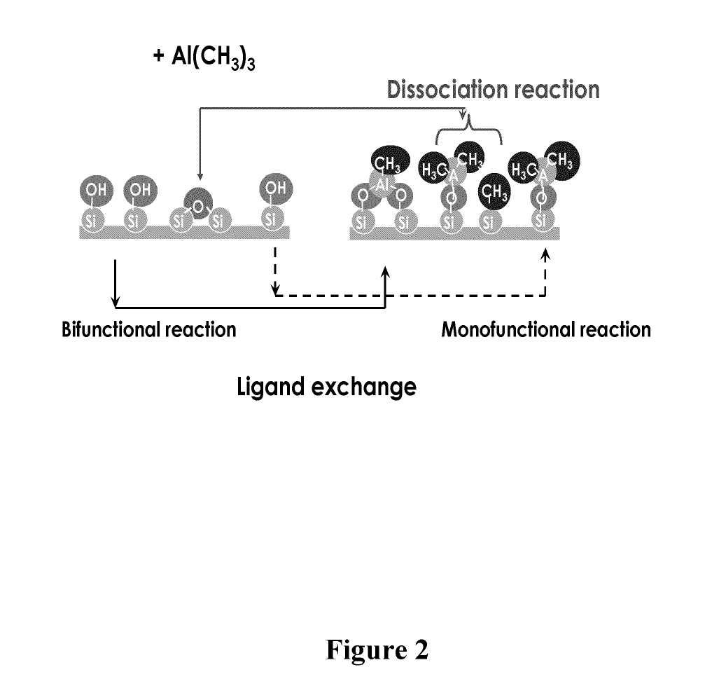

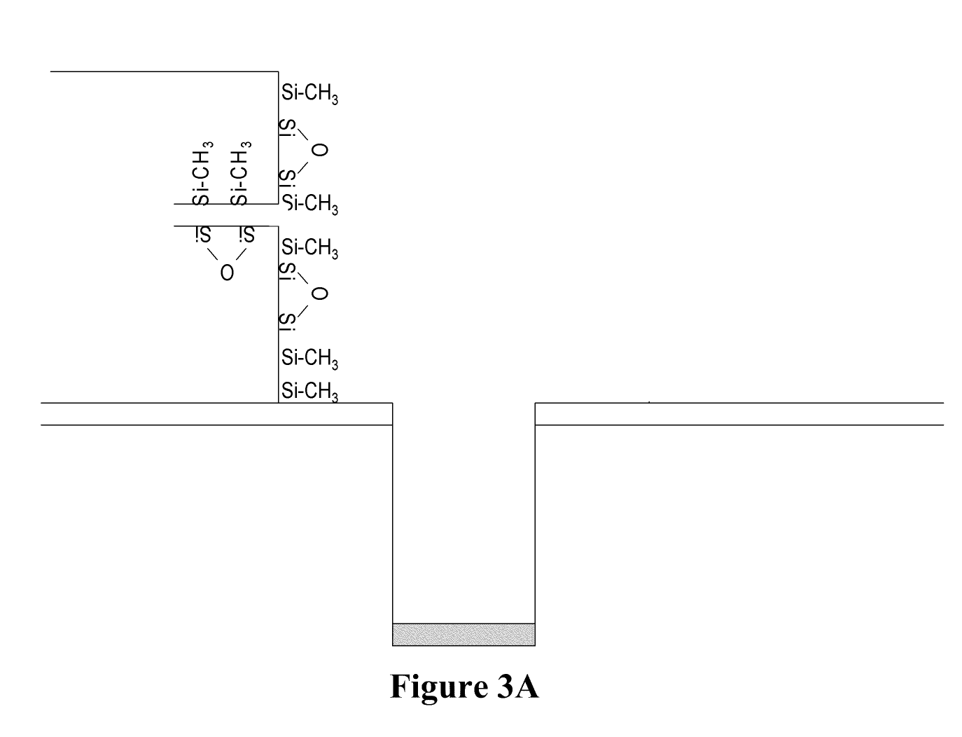

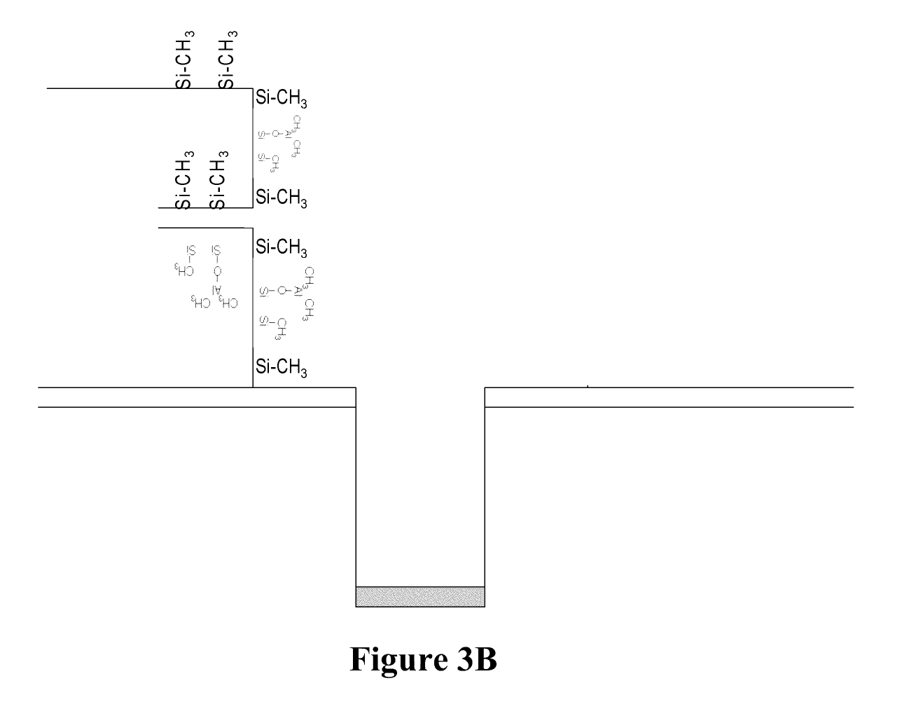

Again, without wishing to be held to a particular theory, it is believed that the selected catalyst reacts with the oxygen bridges (Si—O—Si) on the hydrophobic surface. FIG. 2 illustrates the reaction of TMA (catalyst) with oxygen bridges on a surface. FIG. 3 illustrates the reaction of a catalyst, here TMA, with a low-k Si—CH₃ surface.

As mentioned above, the substrate comprises a hydrophobic surface on which deposition is desired. However, the substrate may comprise other hydrophilic surfaces, and in some embodiments deposition of SiO₂ may be desired on both hydrophilic and hydrophobic surfaces. Thus, in some embodiments a catalyst is selected that is able to react with both types of surfaces and catalyze SiO₂ formation from silanol. A hydrophobic surface comprises CH₃ groups and/or siloxane bridges. In some embodiments the hydrophobic surface does not comprise any significant amount of OH-groups, for example as determined by standard methods, such as IR or NMR. In some embodiments the hydrophobic surface has less than about 1 OH-group per nm², less than 0.5 OH-groups per nm², less than 0.1 OH-groups per nm², or less than 0.05 OH-group per nm². In some embodiments the OH-group concentration might be below 0.01 per nm². In some embodiments a hydrophobic surface is one on which —OH groups can not be detected by IR and/or NMR. In some embodiments a hydrophobic surface has a contact angle measurement of more than 90°.

The thin films deposited by the methods herein may be highly conformal, allowing deposition in thin trenches and other areas with high aspect ratios. The thin films may show good smoothness. The faster growth rates also allow for quicker processing and deposition of silicon dioxide thin films, thereby decreasing process times and increasing throughput.

A typical deposition cycle comprises contacting a substrate on which deposition is desired with at least two reactants. First, a substrate is loaded into a reaction chamber and is heated to a suitable deposition temperature, generally at lowered pressure. Deposition temperatures are maintained below the thermal decomposition temperature of the reactants but at a high enough level to avoid condensation of reactants and to provide the activation energy for the desired surface reactions. Of course, the appropriate temperature window for any given reaction will depend upon a number of factors including the nature of the hydrophobic surface (surface termination) and reactant species involved, as well as the desired growth rate and film qualities.

In some embodiments, the deposition temperature is between an bout 50° C. and about 400° C. In some embodiments the deposition temperature is greater than about 100° C. and the catalytic chemical is an alkylaluminum compound, such as TMA. In some embodiments the catalytic chemical is an alkylboron compound, such as TEB, and the deposition temperature is between about 50° C. and about 400° C., between about 100° C. and about 350° C., or between about 100° C. and about 300° C. In some embodiments the catalytic chemical is an alkylboron compound and the temperature is greater than about 100° C. In some embodiments the deposition temperature is greater than about 300° C. and the catalytic chemical is TEB.

A hydrophobic substrate surface may be a low-k material as described herein. In some embodiments a substrate surface may comprise an organic layer, such as organic polymer film like a polyimide or a film formed during UV-curing of a low-k. The substrate surface can also comprise photoresists that are used in the industry, for example in the semiconductor industry. Other organic hydrophobic surfaces without a substantial amount of reactive OH-groups may also be used in some embodiments. U.S. Publication No. 2011-0159202 describes some exemplary hydrophobic films and is hereby incorporated by reference.

A first reactant comprising a catalytic chemical is selected that is reactive with the hydrophobic surface. The first reactant is conducted or pulsed into the chamber in the form of vapor phase pulse and contacted with the surface of the substrate. Conditions are preferably selected such that no more than about one molecular layer of the first reactant is adsorbed, reacted with or chemisorbed on the substrate surface in a self-limiting manner. The molecular layer of the first reactant forms a catalytic surface comprised of catalytic sites. The appropriate pulsing times can be readily determined by the skilled artisan based on the particular circumstances. For example, the pulsing time can be selected to allow the catalyst to penetrate to a desired depth in the pores of a porous surface. Excess first reactant and reaction byproducts, if any, are removed from the reaction chamber, such as by purging.

Purging the reaction chamber means that vapor phase precursor and/or vapor phase byproducts, if any, are removed from the reaction chamber such as by, evacuating the chamber with a vacuum pump and/or by replacing the gas inside the reactor with an inert gas such as argon or nitrogen. Typical purging times are from about 0.05 to 600 seconds. However, other purge times can be utilized if necessary, such as where highly conformal step coverage over extremely high aspect ratio structures or other structures with complex surface morphology is needed. Also, batch ALD reactors can utilize longer purging times because of increased volume and surface area.

After removal of excess first reactant, a second gaseous silicon reactant, typically a silanol reactant is pulsed into the chamber and contacts the substrate surface. In some embodiments the silanol reactant contacts the formed catalytic surface. The silicon reactant reacts with the surface to form one or more monolayers of silicon dioxide. The pulsing time of the second reactant may be varied, for example to allow the deposition of a film of the desired thickness. Excess silanol and gaseous byproducts of the surface reaction, if any, are removed from the reaction chamber, preferably by purging with the aid of an inert gas and/or evacuation.

The steps of pulsing and purging the first and second reactant may be repeated, if necessary, until a thin film of silicon dioxide of the desired thickness has been formed on a hydrophobic surface of the substrate. In some embodiments a single cycle may be all that is required to obtain a silicon dioxide film of a desired thickness. In other embodiments the steps may be repeated 2, 3, 4, 5, 6, 7, 8, 9, 10 or more times.

Although referred to as a first and second reactant, cycle can begin with either reactant. However, as will be recognized by the skilled artisan, if a cycle begins with the silanol reactant, deposition may not begin until the second deposition cycle. It may be noted that some silanol compounds do not react with hydrophobic low-k surfaces at temperatures below 400 ° C.

As mentioned above, each pulse or phase of each cycle is typically self-limiting. With respect to the catalyst precursor (metal reactant), surface saturation ensures reactant occupation of all available reactive sites (subject, for example, to physical size or “steric hindrance” restraints) and thus ensures excellent step coverage. However, in some embodiments, the metal reactant can be provided in a non-saturating or under-saturating dose. For example, in deep trench structures it is important to form a “collar,” which is an etch-stop layer that must extend only part of the way down the trench. In this example, under-saturated pulses of the metal reactant can be used to preferentially deposit the catalyst along the collar area in comparison to surfaces further down in the trench. In another example, if the hydrophobic surface is part of a layer comprising pores, a predetermined dose of catalyst and/or silanol may be provided such that the reactant only penetrates to a desired depth in the pores. As a result, the silicon dioxide deposition only occurs to the depth the catalyst reached and thus the extent of silicon dioxide deposition within the pores is limited to a desired depth. Thus, in some embodiments, the dose of the catalyst is metered in order to provide a predetermined amount of catalyst and a predetermined amount of deposition of silicon dioxide.

With respect to the silanol reactant, in some embodiments a saturating pulse of silanol is provided. However, because the growth rate of silicon dioxide depends on diffusion of the precursor through the growing film, the growth rate can be controlled, for example by controlling precursor dose and/or purge time. Thus, in some embodiments a non-saturating dose of silanol can be provided. In some embodiments the dose of the silanol reactant and/or exposure time may be limited to provide silicon dioxide to a particular thickness and/or to a particular depth in a given reaction cycle.

In some embodiments a silicon dioxide thin film is formed on a hydrophobic surface of a substrate by selecting a catalyst that is able to react with the hydrophobic surface and carrying out a deposition process comprising one or more silicon dioxide deposition cycles, each silicon dioxide deposition cycle comprising:
providing a first vapor phase reactant pulse comprising a metal catalyst into the reaction chamber to form no more than about a single molecular layer of the catalyst on the hydrophobic surface of the substrate;
removing excess catalyst from the reaction chamber;
providing a second vapor phase reactant pulse comprising a silanol to the reaction chamber; and removing excess second reactant and reaction byproducts, if any, from the reaction chamber.

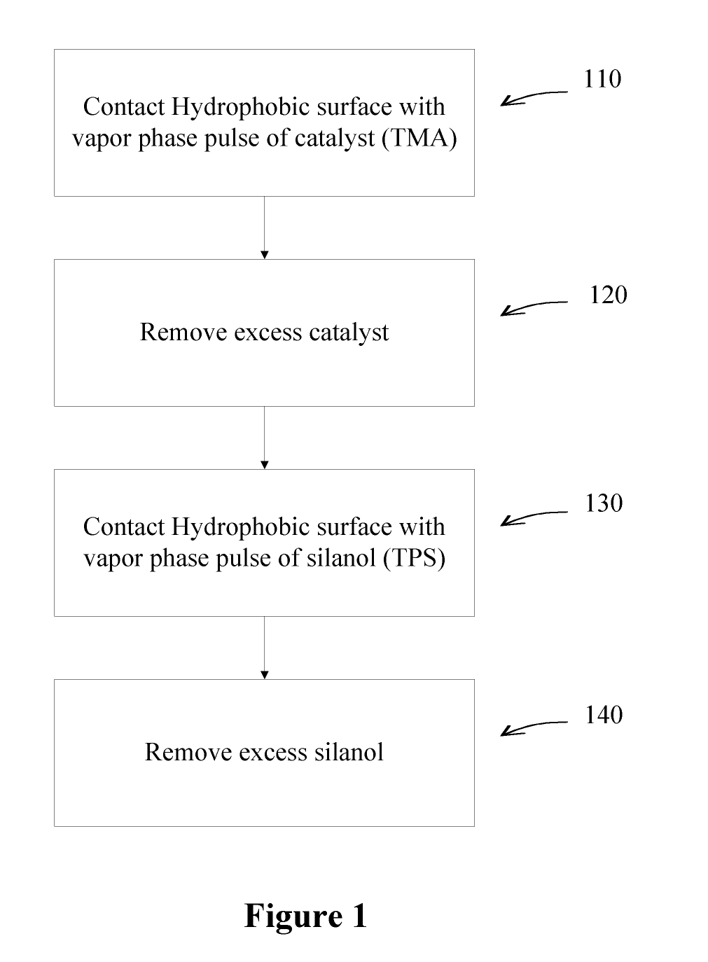

FIG. 1 is a flow chart generally illustrating a method for forming a silicon dioxide thin film in accordance with one embodiment. After selecting an appropriate catalyst that is reactive with the hydrophobic surface on which deposition is desired, the silicon dioxide cycle begins by providing vapor phase catalyst to contact the hydrophobic surface of the substrate in the reaction space 110. As mentioned above, conversion of the hydrophobic surface to a hydrophilic surface is not required, as the catalyst is able to react with the hydrophobic surface. Thus, in some embodiments the hydrophobic surface is not converted to a hydrophilic surface prior to contacting the surface with the catalyst.

In some embodiments the catalyst can comprise a metal, such as one or more of aluminum, boron, zinc and magnesium. However, as mentioned above, the catalyst is selected such that it is reactive with the hydrophobic surface, for example with siloxane bridges on the surface. In some embodiments the catalyst is an alkylalumnium, alkylboron or alkylzinc compound that is able to react with the hydrophobic surface. Other catalysts are described above. For example, the catalyst may comprise trimethyl aluminum (TMA), triethylboron (TEB), or diethyl zinc. Other suitable metal catalysts can be selected such that they catalyze formation of silicon dioxide from a silane reactant on the hydrophobic surface. In some particular embodiments, including the illustrated embodiment, the catalyst is TMA. In other embodiments the catalyst is a boron compound, such as an alkylboron compound, for example TEB.

Catalysts comprising boron are used in some embodiments. As boron has been found to increases the k value less than aluminum, in some embodiments where the hydrophobic material is deposited on a low k dielectric, a boron compound is used as the catalyst. In some embodiments the metal precursor is an organic substituted or unsubstituted boron compound, such as a C₁-C₆ alkylboron compound, for example triethylboron (TEB) or trimethylboron (TMB). In some embodiments the boron compound is haloalkylcompound of boron, such as diethylboronchloride or dimethylboronchloride.

Preferably, the catalyst forms no more than about a single molecular layer of metal on the substrate. Excess catalyst can be purged or removed 120 from the reaction space. Removing excess catalyst can include evacuating some of the contents of the reaction space and/or purging the reaction space with an inert gas, such as helium, argon or nitrogen. In some embodiments purging can comprise turning off the flow of the reactive gas while continuing to flow an inert carrier gas to the reaction space.

Next, a vapor phase silicon source is provided 130 and contacts the substrate in the reaction chamber. One or more of a variety of silicon precursors can be used. However, in the preferred embodiments one or more silanols, such as tris(tert-butoxy)silanol (TBS), tris(isopropoxy)silanol (TIS), and tris(tert-pentoxy)silanol (TPS), are used. Silanols are compounds comprising silicon bound to one or more hydroxyl (OH) groups. In some embodiments, the silanols comprise more than one OH-group bondied directly to the silicon atom. Silanol compounds include, without limitation, alkoxysilanols, alkoxyalkylsilanols, and alkoxysilanediols. In some embodiments, the silicon source is TPS. In other embodiments the silicon source is di(alkoxy)silanediol. A suitable silicon precursor can be selected by the skilled artisan such that it reacts with the molecular layer of the metal precursor on the substrate to form silicon dioxide under the desired reaction conditions, such as at low temperature.

Depending on reaction conditions and the selected silicon precursor, one or more molecular layers of silicon dioxide are formed. In some embodiments more than one molecular monolayer of silicon dioxide is formed in each deposition cycle. In some embodiments the silicon dioxide thickness that is formed is just enough to close or seal the pores of a porous layer.

If necessary, any reaction byproducts and excess silicon precursor can be removed 140 from the reaction space. In some embodiments, the purge step can comprise stopping the flow of silicon precursor while still continuing the flow of an inert carrier gas such as nitrogen or argon.

In some embodiments only a single silanol pulse is provided. In some embodiments a single silanol pulse is used to deposit a silicon dioxide film with a thickness measured on the top surface of the hydrophobic layer on the substrate of more than 5 angstroms.

In some embodiments, more than one silanol pulse is provided in each deposition cycle. For example, a catalyst pulse can be followed by two, three or more silanol pulses. In some embodiments, a catalyst pulse is followed by two silanol pulses. Each silanol pulse may be separated by a purge step. In other embodiments, each silanol pulse is provided after a predetermined time delay, without an intervening purge step.

The silicon dioxide deposition cycle may be repeated a predetermined number of times until a thin film of a desired thickness is formed. In some embodiments, two deposition cycles are used. However, in some embodiments, only a single pulse of the catalytic chemical is provided.

In some embodiments a thin film of silicon dioxide of less than about 2 nm is deposited. In some embodiments a thin film of silicon dioxide of less than about 3 nm is deposited. In some embodiments one or both of the catalyst and the silanol are underdosed in order to obtain deposition of a film of less than about 2 nm or less than about 3 nm. The thin film may be deposited in one deposition cycle or in multiple deposition cycle.

The precursors employed may be solid, liquid or gaseous material under standard conditions (room temperature and atmospheric pressure), provided that the precursors are in vapor phase when it is conducted into the reaction chamber and contacted with the substrate surface. “Pulsing” a vaporized precursor onto the substrate means that the precursor vapor is conducted into the chamber for a limited period of time. Typically, the pulsing time is from about 0.05 to 400 seconds.

In some embodiments, the catalyst, such as an aluminum or boron catalyst, is pulsed for from 0.05 to 10 seconds, more preferably for from 0.1 to 5 seconds and most preferably for about 0.15 to 3.0 seconds. The purge time for the metal precursor can be determined by the skilled artisan, but may be 1 to about 60 seconds and in some embodiments is about 3 seconds.

The silanol reactant is preferably pulsed for from about 0.05 to 400 seconds, more preferably for from 0.1 to 400 seconds, even more preferably 1 to 180 seconds, and most preferably about 30 to 180 seconds. The optimum pulsing time can be determined by the skilled artisan based on the particular circumstances.

The purge time can also be determined by the skilled artisan. Typically, the purge time for the silicon precursor is about the same length as the pulse time or longer. Typically, the longer the pulse of the silicon precursor the longer the purge time used to remove excess reactant. In one embodiment, for example, with 90 second TPS pulses a purge time of about 90 seconds was also used. For longer pulse times, such as 400 seconds, longer purge times could be used. The silicon precursor pulse time can be selected by the skilled artisan based on the particular circumstances, including the desired film growth, reactor configuration, process conditions, and substrate temperature.

A carrier gas can also be used to facilitate the flow of the reactant gases and/or facilitate purging the reactor. The nitrogen carrier gas flow will vary depending on the reactor type, and can be determined by the skilled artisan. For example, a nitrogen carrier gas flow of about 100 to 1000 sccm can be used. Preferably, the nitrogen carrier gas flow is between about 200 and 800 sccm. Even more preferably, the nitrogen carrier gas flow is between 200 and 400 sccm.

The mass flow rate of the precursors can also be determined by the skilled artisan. In one embodiment, for deposition on 300 mm wafers the flow rate of metal precursor is preferably between about 1 and 1000 sccm without limitation, more preferably between about 100 and 500 sccm. The mass flow rate of the metal precursor is usually lower than the mass flow rate of the silicon source, which is usually between about 10 and 10000 sccm without limitation, more preferably between about 100-2000 sccm and most preferably between 100-1000 sccm.

The pressure in the reaction chamber is typically from about 0.1 mTorr to 5 Torr, more preferably from about 0.1 mTorr to about 3 Torr, and most preferably 0.2 mTorr to about 3 Torr. However, in some cases the pressure will be higher or lower than this range, as can be readily determined by the skilled artisan.

Before starting the deposition of the film, the substrate is typically heated to a suitable growth temperature. In some embodiments, the growth temperature of the silicon dioxide thin film is less than about 500° C., less than about 400° C., less than about 300° C., less than about 200° C., less than about 150° C. or even less than about 125° C. Temperatures are typically such that the catalyst does not decompose. In some embodiments the deposition process can be performed at temperatures greater than 300° C., for example in some embodiments in which TEB is used as a catalyst. In some embodiments the deposition process can be performed at temperatures greater than 100° C., for example with TMA as a catalyst. The silicon dioxide deposition may be performed at temperatures below 100° C. with suitable silicon precursors with desired physical properties, such as a low enough vaporization temperature.

The preferred deposition temperature may vary depending on a number of factors such as, and without limitation, the reactant precursors, the pressure, flow rate, the arrangement of the reactor, desired properties of the deposited thin film, and the composition of the substrate including the nature of the material to be deposited on.

The growth rate is a function of a variety of factors, such as deposition temperature and silicon precursor concentration (dose). Silicon precursor dose can be controlled to achieve a desired deposition rate (up to that achieved with a saturating dose). Temperature has an affect on the growth rate of the silicon dioxide thin films with higher growth rates per deposition cycle achieved at lower temperatures. In some embodiments, the growth rate can vary from about 300 nm/pulse to 1 nm/pulse. In some embodiments, the growth rate per cycle is less than 200 Å per cycle. Preferably, the growth rate is above 100 Å per cycle, and even more preferably above 50 Å per cycle. Generally the lower the growth rate the better for the pore sealing as the pore sealing layer should not be too thick as it may negatively impact the electrical properties of the device.

Examples of suitable reactors that may be used include commercially available ALD equipment such as the F-120® reactor, Pulsar® reactor, EmerALD® reactor and Advance® 400 and 412 Series reactor and Stellar™ FLR reactor, available from ASM America, Inc of Phoenix, Ariz., ASM Europe B.V., Almere, Netherlands, and ASM Japan of Tama, Japan, respectively. In addition to these ALD reactors, many other kinds of reactors capable of ALD growth of thin films, including CVD reactors equipped with appropriate equipment and means for pulsing the precursors can be employed. Preferably, reactants are kept separate until reaching the reaction chamber, such that shared pathways for the precursors are minimized. However, other arrangements are possible, such as the use of a pre-reaction chamber as described in U.S. application Ser. No. 10/929,348, filed Aug. 30, 2004 and Ser. No. 09/836,674, filed Apr. 16, 2001, the disclosures of which are incorporated herein by reference.

A cross flow reactor, such as the Pulsar® 3000 is also suitable for the methods described herein and used in some embodiments.

In some embodiments, the reactants are delivered to the reaction space using a showerhead tool.

The growth processes can optionally be carried out in a reactor or reaction space connected to a cluster tool. In a cluster tool, because each reaction space is dedicated to one type of process, the temperature of the reaction space in each module can be kept constant, which improves the throughput compared to a reactor in which the substrate is heated up to the process temperature before each run. Also a cold-wall reactor may be used, for example with only the substrate heated to avoid the growth on the reaction chamber walls may preferably be used.

In one embodiment, SiO₂ is deposited on a substrate in a reaction chamber at a temperature of about 150° C. TMA is pulsed into the reaction chamber for 150 ms, followed by a 3 s purge. TPS is then pulsed into the reaction chamber for 90 s, followed by a 90 s purge.

In some embodiments, SiO₂ is deposited on a substrate in a reaction chamber at a temperature of about 125° C. to about 325° C. using TEB as a catalyst. TEB is pulsed into the reaction chamber, excess TEB is purged and TPS or another silanol is pulsed into the reaction chamber. Excess silanol and reaction by-products, if any, are then removed from the reaction chamber.

The SiO₂ films formed by the methods described herein can be used in a variety of contexts. Silicon dioxide films are used, for example, in a wide variety of semiconductor devices, including CMOS, DRAM, flash, and magnetic head applications. Silicon dioxide is also commonly used as a gate dielectric for CMOS, as an electrical isolation layer, and gap filling layer.

As mentioned above, in some embodiments the silicon dioxide layer can serve as a pore sealing layer on a porous hydrophobic layer, such as a porous low-k material. Increasing porosity can effectively lower the dielectric constant. Accordingly, maximum advantage of the low k material's reduction of parasitic capacitance occurs with maximum porosity. This advantage is balanced against issues of mechanical, chemical and thermal stability during further processing, some of which issues can be resolved by techniques independent of adjusting porosity. While the methods disclosed herein are applicable to insulating layers with any level of porosity, the porosity of the low k films is desirably greater than about 10%, more preferably greater than about 20% and most preferably greater than about 25%.

In some embodiments, the low-k material on which a silicon dioxide layer is formed is an SiOCH film with a dielectric constant (k) of 2.3<k<2.8 and an elastic modulus (EM) of greater than 5 GPa, more preferably a k of 2.4<k<2.6 and an elastic modulus of 8 GPa<EM. See, for example, U.S. Pat. No. 7,807,566, which is incorporated by reference herein. Other low-k materials are described in US 2010-00151151, which is also incorporated by reference herein.

The sealing or blocking layer can be formed by optimizing the silicon dioxide deposition cycle to block the pores of the low k layers before significant penetration into the layers. Previous work has been conducted to determine the conditions under which porous materials can be coated by ALD. See A. W. Ott., J. W. Klaus, J. M. Johnson, S. M. George, K. C. McCarley, J. D. Way, “Modification of Porous Alumina Membranes Using Al₂O₃ Atomic Layer Controlled Deposition,” Chem. Mater. Vol. 9, No. 3 (1997), p. 707-714; and Suvi Haukka, Eeva-Liisa Lakomaa, Tuomo Suntola, “Chemisorption of chromium acetylacetonate on porous high surface area silica,” Appl. Surf. Sci. Vol. 75, No. 1-4 (1994), pp. 220-227. See also U.S. Pat. Nos. 6,482,733 and 6,759,325. Each of the references noted above are hereby expressly incorporated herein by reference. The skilled artisan will appreciate in view of the present disclosure that, conversely, the conditions for avoiding conformal coating of a porous material can be determined using similar techniques. Advantageously, the silicon dioxide deposition process for blocking the pores of the low k material can be followed in situ by high conformality ALD layers (e.g., adhesion, barrier, electroplating seed layer.

As discussed above, the reactants can be pulsed into the reaction chamber in an inert carrier gas. In the first pulse of catalyst, the surface of the substrate is lined with the metal-containing species. In addition, the catalyst is able to penetrate into the porous insulating layer by diffusion. If necessary, the first pulse can be lengthened or shortened, ensuring penetration of the metal source gas to a desired depth in the porous insulating layer. In some embodiments the dose (concentration) of the catalyst is predetermined, such that the catalyst is only able to penetrate the porous material to a desired depth. By limiting the deposition to the outermost pores of the insulating material, silicon dioxide deposition can be limited to a particular depth and a sealing layer can be deposited without adversely affecting the insulating qualities of the material.

In some embodiments, the pulse of the catalyst is an under-saturated dose such that it penetrates only to a limited depth in the low-k material, preferably to depth of less than about 20 nm, more preferably to the depth of less than about 10 nm and most preferably to the depth of less than about 5 nm.

Following the first pulse, the unreacted catalyst and by-products, if any, are purged from the reaction chamber, for example with a pulse of inert gas. In some embodiments, the purge is insufficient to remove all of the catalyst from the pores and some remains trapped in the pores of the insulating material. The purge pulse may be optimized to purge reactants from the reaction space and other structures, for example, the trenches and vias, but not optimized to purge out the pores. Alternately, the purge pulse may be shortened to ensure that metal reactant gas remains within the pores of the insulating material. In other embodiments the purge is sufficiently long to remove essentially all catalyst, even from the pores.

A second, silicon chemistry, typically a silanol as discussed above, is pulsed into the chamber following the purge. The second chemistry forms a layer of silicon dioxide on the surface. Additionally, the second chemistry diffuses into the insulating material where it reacts and forms a layer of silicon dioxide within the pores. As the depth of penetration (and adsorption) of the catalyst has been limited, the silicon dioxide will only be deposited to the depth of penetration of the catalyst into the pores. The result will be the deposition of the most silicon dioxide toward the surface of the porous material. This will narrow the neck of the outermost pores, further limiting diffusion into the porous insulating material during subsequent deposition cycles (if subsequent cycles are even necessary). In some embodiments, a single deposition cycle will effectively seal the porous material. In other embodiments the deposition cycle can be repeated multiple times until the porous material is sealed effectively. In some embodiments, the dose of the silicon chemistry is limited to provide for deposition of silicon dioxide to a limited depth in the porous layer. In some embodiments, the dose of the silicon chemistry is carefully controlled to achieve a limited deposition of silicon oxide in terms of both thickness and in penetration depth. In some embodiments the deposited film is less than 3 nm thick, more preferably less than 2 nm thick.

Repetition of the deposition cycle, if necessary, will narrow the neck of the first pore further by increasing the thickness of the deposited silicon dioxide layer and will eventually lead to a continuous, sealing layer blocking off the pores. By limiting the depth of penetration of the catalyst and/or the silanol, the porous insulating material can be sealed without significantly reducing the insulating properties of the material. The number of repetitions of the deposition cycle needed to seal off the pores will depend, in part, on the pore size and can be determined by the skilled artisan through routine experimentation

In some embodiments, the sealing layer blocks the pores and prevents entry of reactants after the pores have been blocked, particularly before any high conformality ALD process, or other vapor deposition process, begins. The silicon dioxide also converts the hydrophobic surface to a hydrophilic surface (containing OH-groups) suitable further ALD processing. For example, in some embodiments deposition of the barrier layer by atomic layer deposition (ALD) is possible immediately following SiO₂ deposition.

The processes described herein are also useful for applications that require depositing silicon dioxide on organic materials or three dimensional structures, such as through vias or shallow trenches because of the ability to deposit highly conformal thin silicon dioxide films.

The following non-limiting examples illustrate certain preferred embodiments of the invention.

### EXAMPLE 1

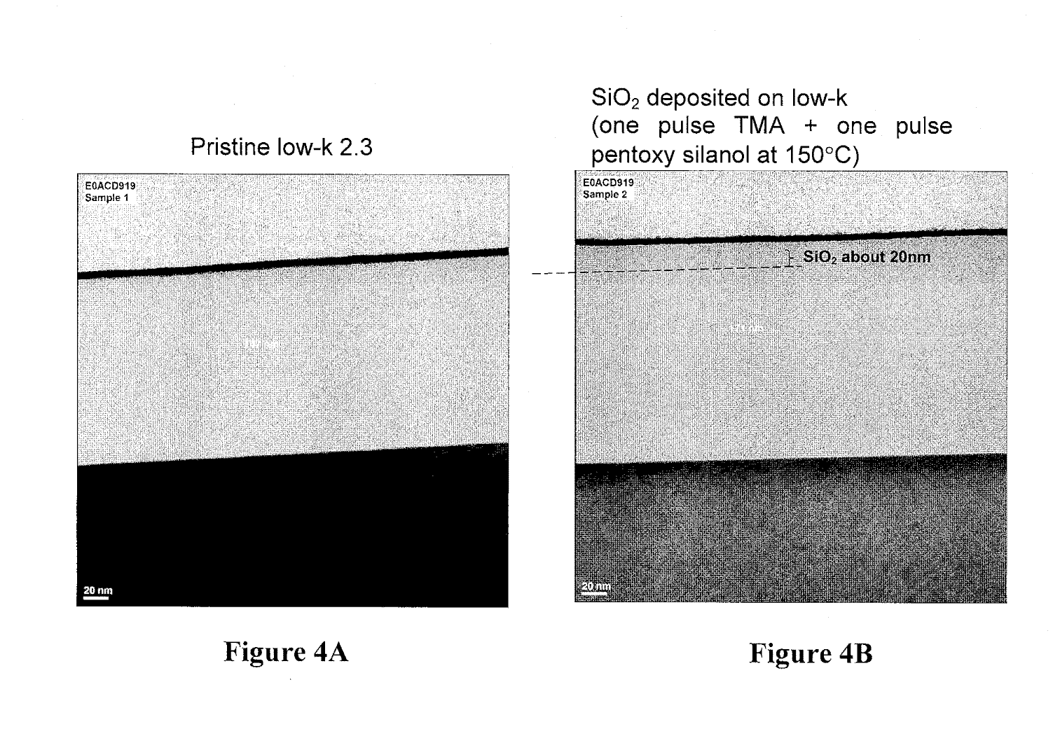

A series of experiments were performed to deposit silicon dioxide using TPS as a silicon precursor and TMA as a catalyst on a hydrophobic surface. A substrate comprising a low-k material (ASM Japan ELK 2.3) with a hydrophobic surface was contacted with TMA, followed by TPS at a temperature of 150° C. A similar reaction was performed in the absence of TMA. In the absence of TMA, no silicon dioxide growth was observed on the low-k material. However, a single pulse of TMA, followed by TPS, produced silicon dioxide growth of approximately 20 nm, which can be seen in as difference in thickness in the TEM images in FIG. 4.

### EXAMPLE 2

Silicon dioxide is deposited on a porous, low-k material using a controlled dose of TMA as a catalyst. TPS used as the silanol.

A reactor is equipped with computer-controlled pneumatic dose valves for controlled precursor deposition. Alternating exposures of TMA and TPS are used for silicon dioxide thin film deposition. The dose of TMA is predetermined such that the depth the TMA penetration into the pores is limited and essentially only reactive sites on the top-most surface of the low-k material react with the TMA.

### EXAMPLE 3

A copper barrier layer is formed by first depositing silicon dioxide on a hydrophobic surface of a substrate comprising a low-k material. The substrate is contacted with a pulse of TMA, the excess TMA is evacuated from the reaction space and the substrate is contacted with a pulse of TPS, thereby forming a silicon dioxide layer on the hydrophobic surface. The silicon dioxide converts the hydrophobic surface to a hydrophilic surface suitable for deposition of the barrier layer by atomic layer deposition (ALD). A barrier layer is subsequently deposited on the silicon dioxide layer by ALD.

### EXAMPLE 4

A sidewall spacer is formed by an process comprising alternating and sequential pulses of TMA and TPS. A first layer comprising silicon dioxide is deposited by alternately and sequentially contacting a substrate comprising a hydrophobic surface with pulses of TMA and TPS. A silicon nitride layer is then deposited on top of the silicon dioxide layer.

### EXAMPLE 5

A series of experiments were performed to deposit silicon dioxide using TPS as a silicon precursor and TEB as a catalyst on a hydrophobic surface. A substrate comprising a low-k material (ASM Japan ELK 2.3) with a hydrophobic surface was contacted with TEB, followed by a saturating dose of TPS at temperatures from about 125° C. to about 325° C. Single pulses of TEB, followed by a saturating dose of TPS, produced silicon dioxide growth of approximately from 9-20 nm. Further EELS analysis of the deposited silicon oxide layers showed them to provide resistance to TiC1₄ and TMA penetration into the low-k film. In a comparison sample where no silicon oxide pore sealing layer was formed, TMA diffused into the low-k film.

It will be appreciated by those skilled in the art that various modifications and changes can be made without departing from the scope of the invention. Similar other modifications and changes are intended to fall within the scope of the invention, as defined by the appended claims.

We claim:

1. A method of depositing a silicon dioxide thin film on a hydrophobic surface of a substrate, the method comprising:
contacting the hydrophobic surface comprising siloxane bridges with a vapor phase pulse of a catalyst that is reactive with the siloxane bridges and comprises aluminum, boron or zinc; and
subsequently contacting the hydrophobic surface with a vapor phase pulse of a silanol.

2. The method of claim 1, wherein the hydrophobic surface is a porous low-k film.

3. The method of claim 1, wherein the hydrophobic surface comprises CH₃-groups.

4. The method of claim 1, wherein the hydrophobic surface comprises less than about 1-OH group per nm².

5. The method of claim 4, wherein the hydrophobic surface does not comprise —OH groups.

6. The method of claim 1, additionally comprising selecting a catalyst that is reactive with the hydrophobic surface prior to contacting.

7. The method of claim 1, wherein the hydrophobic surface is photoresist.

8. The method of claim 1, wherein the method is performed at a temperature above about 100° C.

9. The method of claim 8, wherein the method is performed at a temperature above about 300° C.

10. The method of claim 1, wherein the catalyst is an alkylboron, alkylaluminum or alkylzinc compound.

11. The method of claim 10, wherein the catalyst is trimethyl aluminum (TMA), triethylboron (TEB) or diethyl zinc.

12. The method of claim 11, wherein the catalytic chemical is triethylboron (TEB).

13. The method of claim 1, wherein the catalyst has the formula MRₓA₃₋ₓ, wherein x is from 1 to 3, R is a C₁-C₅ alkyl ligand, M is B or Al and A is a halide, alkylamine, amino, silyl or derivative thereof.

14. The method of claim 1, wherein the silanol has more than one —OH group bonded directly to the silicon atom.

15. The method of claim 1, wherein the silanol is selected from tris(tertbutoxy)silanol, (^{t}BuO)₃SiOH and tris(tertpentoxy)silanol.

16. The method of claim 1, wherein the silanol is di(alkoxy)silanediol.

17. The method of claim 1, wherein the thickness of the silicon dioxide film is less than about 2 nm.

18. The method of claim 1, wherein a single deposition cycle is carried out.

19. The method of claim 1, wherein the vapor phase pulse of the catalytic chemical comprises a predetermined amount of the catalytic chemical.

20. The method of claim 19, wherein the predetermined amount of the catalytic chemical is an undersaturating dose.

21. The method of claim 1, wherein the silicon dioxide film is deposited on a porous low-k surface and the catalyst is TEB.

22. The method of claim 1, wherein the silicon dioxide film is deposited on a three-dimensional structure.

23. The method of claim 22, wherein the three-dimensional structure is selected from a damascene structure, vias and trenches.

24. The method of claim 1, wherein the substrate additionally comprises hydrophilic surfaces.

25. The method of claim 24, wherein the silicon dioxide is deposited selectively on the hydrophobic surfaces.

26. The method of claim 24, wherein the silicon dioxide is deposited only on the hydrophobic surfaces.

27. The method of claim 24, wherein the silicon dioxide is deposited on both the hydrophobic and hydrophilic surfaces.

28. The method of claim 1, wherein the hydrophobic surface is not treated to form —OH groups prior to contacting with the catalyst.

29. A method of depositing silicon dioxide on a surface of a porous, low-k material, the method comprising one or more deposition cycles, each cycle comprising:
providing an undersaturating dose of vapor phase metal catalyst into the reaction chamber to form no more than about a single molecular layer of the metal catalyst on the surface;
removing excess metal catalyst from the reaction chamber, if any;
providing a vapor phase reactant pulse comprising a silicon precursor to the reaction chamber such that the silicon precursor reacts with the metal catalyst on the surface; and
removing excess silicon precursor and any reaction byproducts from the reaction chamber, wherein a silicon dioxide layer is formed that seals the pores of the low-k material, wherein the surface of the low-k material is hydrophobic and has not been treated to form —OH groups prior to providing the metal catalyst.

30. The method of claim 29, wherein the metal catalyst comprises an alkylaluminum, alkylboron or alkylzinc compound.

31. The method of claim 30, wherein the metal catalyst comprises trimethyl aluminum.

32. The method of claim 29, wherein the silicon precursor comprises a silanol.

33. The method of claim 33, wherein the silanol comprises tris(tert-pentoxy)silanol.

34. A method of depositing a silicon dioxide thin film on a hydrophobic surface of a substrate comprising:
contacting the hydrophobic surface with a vapor phase pulse of triethyl boron; and
subsequently contacting the hydrophobic surface with a vapor phase pulse of a silanol, wherein the deposited thin film is less than 2 nm thick.

35. The method of claim 34, wherein the hydrophobic surface comprises less than about 1-OH group per nm².
